(19) United States
(12) Patent Application Publication
(10) Pub. No.: US 2017/0092576 A1
(43) Pub. Date: Mar. 30, 2017

(54) CONTACTING NANO-IMPRINTED CROSS-POINT ARRAYS TO A SUBSTRATE

(71) Applicant: HGST Netherlands B.V., Amsterdam (NL)

(72) Inventor: Daniel R. SHEPARD, North Hampton, NH (US)

(73) Assignee: HGST Netherlands B.V.

(21) Appl. No.: 14/869,462

(22) Filed: Sep. 29, 2015

(51) Int. Cl. H01L 23/528; H01L 21/768

(52) U.S. Cl. CPC H01L 23/528; H01L 21/76897

(57) ABSTRACT

Embodiments of the present disclosure generally relate to memory devices having nano-imprinted patterns interconnected to conventionally processed circuitry and a method of fabrication thereof. The memory device includes a plurality of conductive traces, a substrate having a plurality of conductive pads and a plurality of conductive posts. Each conductive pad is sized to account for alignment error inherent in the nano-imprinting process. Each conductive post is coupled between a conductive trace and a conductive pad allowing interconnection of the very finely sized features of nano-imprint lithography to the larger features of a conventionally patterned wafer.

### BACKGROUND OF THE DISCLOSURE

Field of the Disclosure

Embodiments of the present disclosure generally relate to semiconductor manufactured memory devices and more particularly, to memory devices having nano-imprinted patterns interconnected to conventionally processed circuitry.

Description of the Related Art

Semiconductor manufacturing of memory devices allows for high density to be achieved by constructing the arrays of data bits at very small geometries. Traditionally, photolithography has been used to construct these arrays. Photolithography, however, has its disadvantages. Photolithography tools are expensive to manufacture, oftentimes costing tens of millions of dollars per tool.

Alternatives to photolithography have been proposed. One such alternative is nano-imprint lithography. Nano-imprint lithography allows for the replication of features as small as 10 nanometers and below. The process of nano-imprinting includes imprinting a pattern into a polymer, which can then be used to pattern features on a semiconductor wafer. Nano-imprint lithography has a relatively low cost. However, due to the semi-fluidic nature of the polymer, alignment precision cannot match the small size of the imprinted features and an alignment error results.

Thus, what is needed is a method to enable the benefits of nano-imprinting while being able to cost effectively interconnect such nano-imprinted patterns to traditionally processed circuitry in a wafer.

### SUMMARY OF THE DISCLOSURE

Embodiments of the present disclosure generally relate to memory devices having nano-imprinted patterns interconnected to conventionally processed circuitry and a method of fabrication thereof. The memory device includes a plurality of conductive traces, a substrate having a plurality of conductive pads and a plurality of conductive posts. Each conductive pad is sized to account for alignment error inherent in the nano-imprinting process. Each conductive post is coupled between a conductive trace and a conductive pad allowing interconnection of the very finely sized features of nano-imprint lithography to the larger features of a conventionally patterned wafer.

In one embodiment, a memory device is disclosed. The memory device includes a plurality of conductive traces. The plurality of conductive traces are disposed in a common plane. A first conductive trace of the plurality of conductive traces has a first length. A second conductive trace of the plurality of conductive traces has a second length and the second length is less than the first length. The memory device also includes a substrate having a plurality of conductive pads formed therein. The memory device also includes a plurality of conductive posts. A first conductive post of the plurality of conductive posts is coupled between the first conductive trace and a first conductive pad of the plurality of conductive pads. A second conductive post of the plurality of conductive posts is coupled between the second conductive trace and a second conductive pad of the plurality of conductive pads.

In another embodiment, a memory device is disclosed. The memory device includes a plurality of conductive traces disposed in a common plane. The memory device also includes a substrate having a plurality of conductive pads formed therein. A first conductive pad of the plurality of conductive pads is spaced from a second conductive pad of the plurality of conductive pads in both an X dimension and a Y dimension. The memory device also includes a plurality of conductive posts. A first conductive post of the plurality of conductive posts extends between the first conductive pad and a first conductive trace of the plurality of conductive traces. A second conductive post of the plurality of conductive posts extends between the second conductive pad and a second conductive trace of the plurality of conductive traces.

In another embodiment, a method is disclosed. The method includes forming one or more conductive pads on a first layer, depositing photoresist over the one or more conductive pads, aligning an imprint lithography stamp representing a second layer to the first layer, and concurrently forming one or more conductive posts and one or more conductive traces in the second layer using imprint lithography. The alignment of the second layer to the first layer includes an alignment error in both an X dimension of ±ΔX and an alignment error in a Y dimension of ±ΔY. Each of the conductive posts has a size of F_{X} in the X dimension and a size of F_{Y} in the Y dimension. Each of the conductive pads has a size that is at least 2ΔX−F_{X} in the X dimension and at least 266 Y−F_{Y} in the Y dimension. Each of the one or more conductive posts contacts both a conductive pad and a conductive trace.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 is a schematic diagram of a memory array according to one embodiment described herein.

FIG. 2 is a schematic perspective view of the memory array according to one embodiment described herein.

FIG. 3 is a is a negative image topography of a pattern that could be used as a stamp for nano-imprinting a plurality of conductive traces having self-aligned conductive posts onto a substrate according to one embodiment described herein.

FIGS. 4A-4E depict top down views of one or more conductive traces, each having a self-aligned conductive post interconnected to a respective conductive pad on a substrate according to one embodiment described herein.

FIG. 5 is a cross-section of a wafer having nano-imprinted patterns interconnected to conventionally processed transistor circuitry according to one embodiment described herein.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

In the following, reference is made to embodiments of the disclosure. However, it should be understood that the disclosure is not limited to specific described embodiments. Instead, any combination of the following features and elements, whether related to different embodiments or not, is contemplated to implement and practice the disclosure. Furthermore, although embodiments of the disclosure may achieve advantages over other possible solutions and/or over the prior art, whether or not a particular advantage is achieved by a given embodiment is not limiting of the disclosure. Thus, the following aspects, features, embodiments and advantages are merely illustrative and are not considered elements or limitations of the appended claims except where explicitly recited in a claim(s). Likewise, reference to “the disclosure” shall not be construed as a generalization of any inventive subject matter disclosed herein and shall not be considered to be an element or limitation of the appended claims except where explicitly recited in a claim(s).

Embodiments of the present disclosure generally relate to memory devices having nano-imprinted patterns interconnected to conventionally processed circuitry and a method of fabrication thereof. The memory device includes a plurality of conductive traces, a substrate having a plurality of conductive pads and a plurality of conductive posts. Each conductive pad is sized to account for alignment error inherent in the nano-imprinting process. Each conductive post is coupled between a conductive trace and a conductive pad allowing interconnection of the very finely sized features of nano-imprint lithography to the larger features of a conventionally patterned wafer.

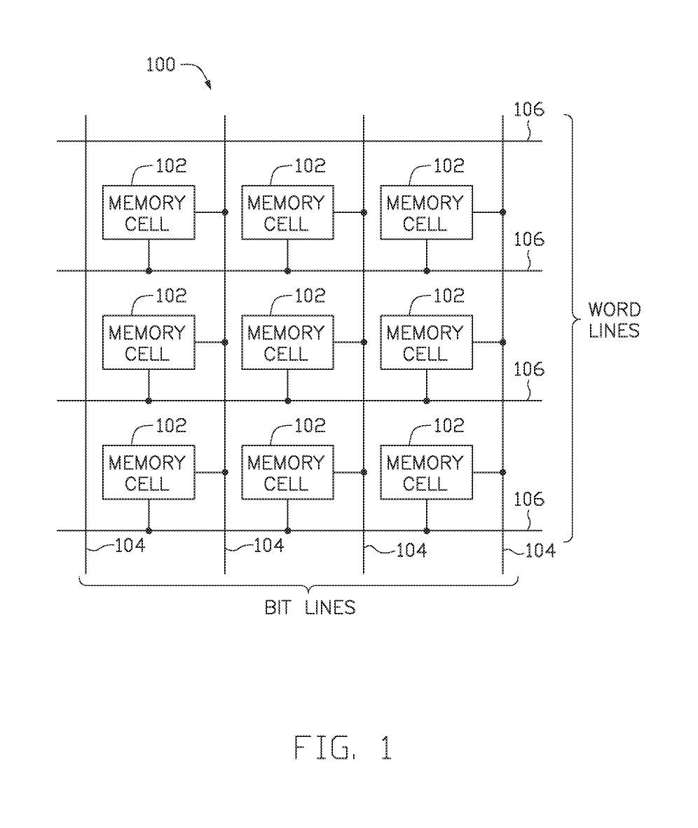

FIG. 1 is a schematic diagram of a memory array 100 according to one embodiment described herein. The memory array 100 includes a plurality of memory cells 102, a first plurality of parallel lines 104 and a second plurality of parallel lines 106. The first plurality of parallel lines 104 run orthogonal to the second plurality of parallel lines 106. The first plurality of parallel lines 104 represent bit lines. The second plurality of parallel lines 106 represent word lines. Each memory cell 102 is coupled to a bit line 104 and a word line 106. Co-linear memory cells 102 are coupled to one common line and one line not in common with the other co-linear memory cells.

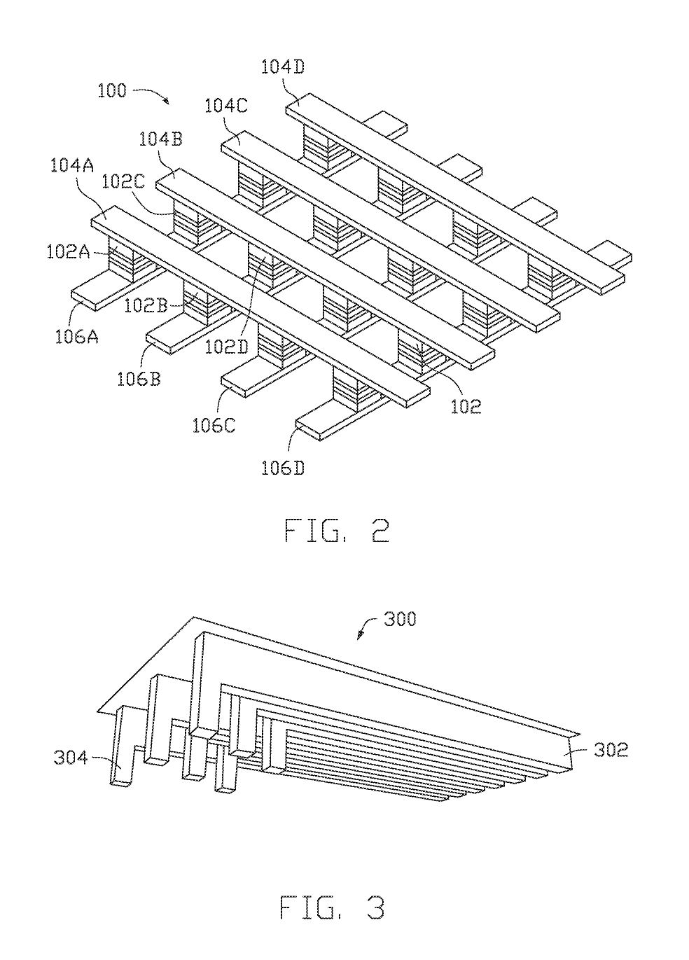

FIG. 2 is a schematic perspective view of the above described memory array 100 according to one embodiment described herein. The first plurality of parallel lines 104 are disposed in a common plane. The second plurality of parallel lines 106 are disposed in a common plane spaced above the first plurality of parallel lines 104. The array 100 is arranged such that a first memory cell 102A is coupled to a first line 104A of the first plurality of parallel lines 104. The first memory cell 102A is also coupled to a first line 106A of the second plurality of parallel lines 106. A second memory cell 102B is coupled to the first line 104A and a second line 106B of the second plurality of parallel lines 106. A third memory cell 102C is coupled to a second line 104B of the first plurality of parallel lines 104. The third memory cell 102C is also coupled to the first line 106A. A fourth memory cell 102D is coupled to both the second line 104B and second line 106B.

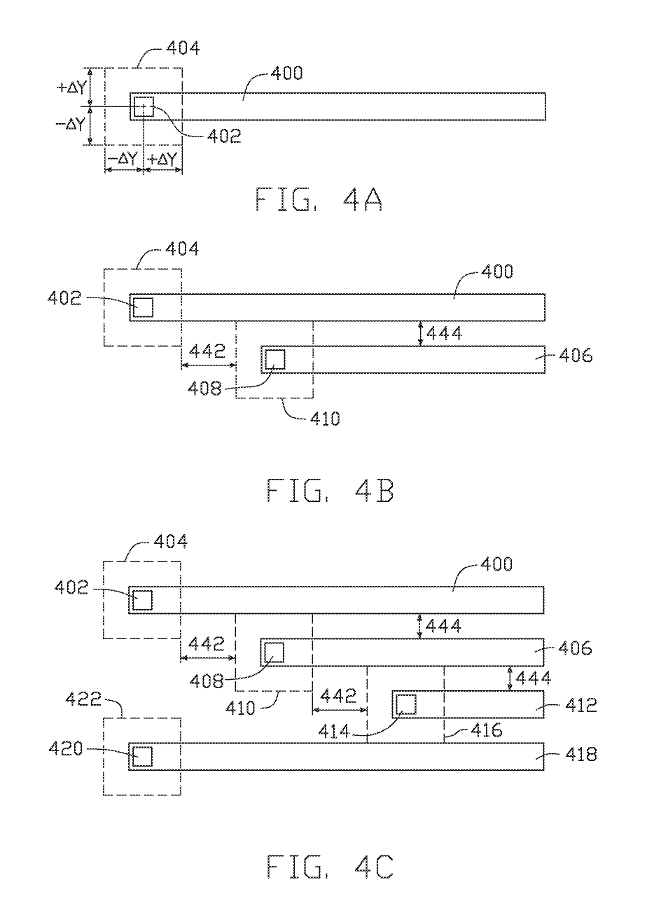

FIG. 3 is a negative image topography of a pattern that could be used as a nano-imprint stamp 300 for nano-imprinting a plurality of conductive traces having self-aligned conductive posts onto a substrate according to one embodiment described herein. The plurality of conductive traces will be disposed in a common plane once printed. The stamp 300 includes a trace portion 302 and a post portion 304. The trace portion 302 is used to imprint the location where the conductive traces will be disposed. Similarly, the post portion 304 is used to imprint the location where the conductive posts will be formed. The trace portion 302 and post portion 304 are prealigned such that after the stamp 300 is removed from the substrate, the conductive material will be formed on the substrate such that the traces and posts will be self-aligned.

The nano-imprint stamp 300 may be made by the various techniques for fabricating nano-imprinting stamps well known to those skilled in the art of nano-imprint lithography. In one embodiment, the nano-imprint stamp 300 can be formed directly by lithography and etching of the topography of the reversed pattern. In another embodiment, the nano-imprint stamp 300 could be patterned and etched as a positive image, which could then be used as a parent from which child pattern stamps are made as a complementary negative image. In one embodiment, the nano-imprint stamp 300 is made using e-beam lithography. In another embodiment, the nano-imprint imprint stamp 300 is made using photolithography. In one embodiment the nano-imprint stamp 300 may comprise Si. In another embodiment the nano-imprint stamp 300 may comprise Si₂O.

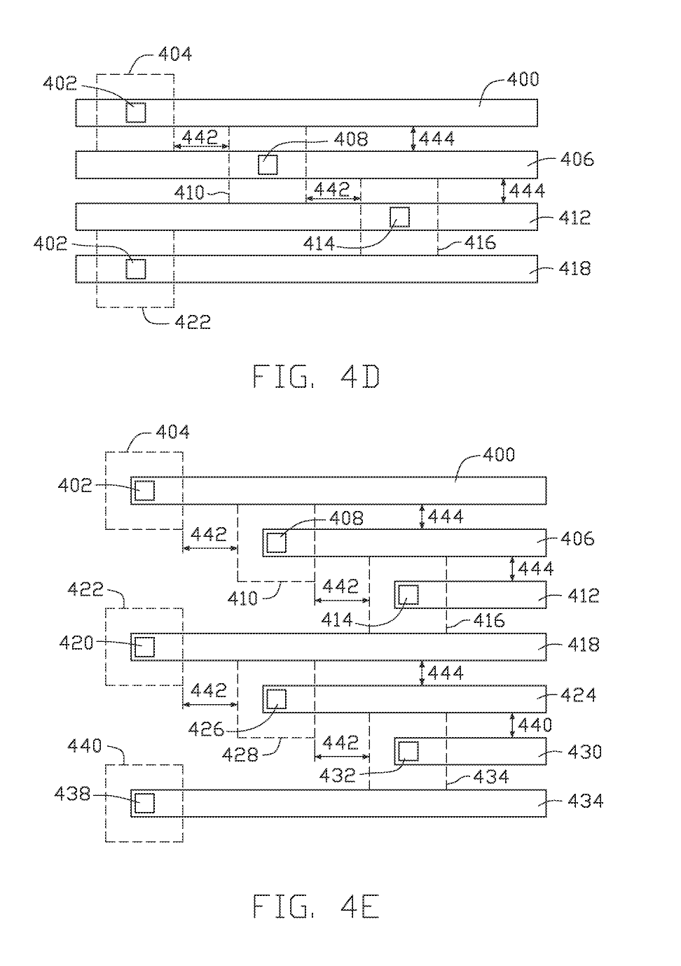

FIGS. 4A-4E depict top down views of one or more conductive traces, each having a self-aligned conductive post interconnected to a respective conductive pad on a substrate according to one embodiment described herein.

FIG. 4A depicts a top down view of a first conductive trace 400 having a first conductive post 402 to be interconnected with a first conductive pad 404, which is deposited on a substrate. The first conductive post 402 is self-aligned to the first conductive trace 400. While the first conductive trace 400 and the first conductive post 402 do not vary relative to one another, the resulting position relative to a substrate can vary in both an X dimension and a Y dimension. As shown in FIG. 4A, the first conductive pad 404 has a length and a width that is substantially larger than the length and width of the first conductive post 402. As will be explained below, the first conductive pad 404 is larger to permit misalignment of the stamp 300. Even when there is a slight misalignment of the stamp 300, the first conductive post 402 may still be formed in electrical contact with the first conductive pad 404.

FIG. 4B is a top down view of a first conductive trace 400 and a second conductive trace 406 having a first conductive post 402 and a second conductive post 408 to be interconnected with a first conductive pad 404 and a second conductive pad 410, respectively. The conductive pads 404 and 410 are deposited on a substrate. Between the conductive pads 404 and 410 is X dimension spacing 442 and Y dimension spacing 444 The X dimension spacing 442 relates to substrate geometry and lithography whereas the Y dimension spacing 444 relates to nano-imprint geometry.

In one embodiment, the first conductive trace 400 has a first length and the second conductive trace 406 has a second length. The second length is less than the first length. As noted above, the conductive pads 404, 410 are staggered. By staggering the conductive pads 404, 410, and hence, the conductive posts 402, 408 and conductive traces 400, 406, the footprint of the device is reduced. The conductive pads 404, 410 must be spaced apart by a distance 442 in both the X and Y directions. The distance 442 is greater than the distance 444 between adjacent traces 400, 406. Hence, if the conductive pads 404, 410 were not staggered, then the distance 444 between adjacent traces 400, 406 would have to be at least as great as distance 442. Furthermore, if the conductive pads 404, 410 were not staggered, then the conductive pads 404, 410 would necessarily overlap if the traces 400, 406 were spaced apart by distance 444. Overlapping conductive pads 404, 410 would, in essence, be a single, large conductive pad which would render individual interaction with the respective posts 402, 408 impossible.

FIG. 4C is a top down view of a first conductive trace 400, a second conductive trace 406, a third conductive trace 412 and a fourth conductive trace 418, having a first conductive post 402, a second conductive post 408, a third conductive post 414 and a fourth conductive post 420, which are to be interconnected to a first conductive pad 404, a second conductive pad 410, a third conductive pad 416 and a fourth conductive pad 422, respectively. The conductive pads 404, 410, 416 and 422 are deposited on a substrate. Each of the conductive pads 404, 410, 416 and 422 is spaced apart with X dimension spacing 442 and Y dimension spacing 444, such that the conductive pads 404, 410, 416 and 422 are staggered.

In one embodiment, the first conductive trace 400 has a first length, the second conductive trace 406 has a second length, the third conductive trace 412 has a third length and the fourth conductive trace 418 has the first length. The second length is less than the first length and the third length is less than the second length. The lengths of the first conductive trace 400 and the fourth conductive trace 418 are equal. In another embodiment, the first length, the second length and the third length are equal as shown in FIG. 4D.

FIG. 4D is a top down view of a first conductive trace 400, a second conductive trace 406, a third conductive trace 412 and a fourth conductive trace 418, having a first conductive post 402, a second conductive post 408, a third conductive post 414 and a fourth conductive post 420, which are to be interconnected to a first conductive pad 404, a second conductive pad 410, a third conductive pad 416 and a fourth conductive pad 422, respectively. The conductive pads 404, 410, 416 and 422 are deposited on a substrate. Each of the conductive pads 404, 410, 416 and 422 is spaced apart with X dimension spacing 442 and Y dimension spacing 444, such that the conductive pads 404, 410, 416 and 422 are staggered. As shown, the conductive posts 402, 408, 414 and 420 are connected to a conductive trace of the plurality of conductive traces at a position along the conductive trace that is spaced from an end.

FIG. 4E is a top down view of a plurality of conductive traces 400, 406, 412, 418, 424, 430 and 436, having conductive posts 402, 408, 414, 420, 426, 432 and 438, respectively. The conductive posts 402, 408, 414, 420, 426, 432 and 438 are to be interconnected with conductive pads 404, 410, 416, 422, 428, 434 and 440, respectively. The conductive pads 404, 410, 416, 422, 428, 434 and 440 are deposited on a substrate. Each of the conductive pads 404, 410, 416, 422, 428, 434 and 440 is spaced apart with X dimension spacing 442 and Y dimension spacing 444, such that the conductive pads 404, 410, 416, 422, 428, 434 and 440 are staggered.

In one embodiment, each of the plurality of conductive traces 400, 406, 412, 418, 424, 430 and 436 has a length. The second conductive trace 406 has a length less than the length of the first conductive trace 400. The third conductive trace 412 has a length less than the second conductive trace 406. The fourth conductive trace 418 has a length equal to the length of the first conductive trace 400. The fifth conductive trace 424 has a length equal to the length of the second conductive trace 406. The sixth conductive trace 430 has a length equal to the length of the third conductive trace 412. The seventh conductive trace 436 has a length equal to the length of the fourth conductive trace 418. In another embodiment, each of the plurality of conductive traces 400, 406, 412, 418, 424, 430 and 436 are of equal length.

In one embodiment, the width of the conductive posts 402, 408, 414, 420, 426, 432 and 432 are equal to the width of the respective conductive traces 400, 406, 412, 418, 424, 430 and 436.

In one embodiment, the conductive posts 402, 408, 414, 420, 426, 432 and 432 are connected at an end of the respective conductive traces 400, 406, 412, 418, 424, 430 and 436. In another embodiment, the conductive posts 402, 408, 414, 420, 426, 432 and 432 are connected to the respective conductive traces 400, 406, 412, 418, 424, 430 and 436 at a position along the conductive trace that is spaced from an end as shown in FIG. 4D.

In one embodiment, the permitted alignment error of the conductive traces 400, 406, 412, 418, 424, 430 and 436 and the conductive posts 402, 408, 414, 420, 426, 432 and 432 in an X dimension is ±ΔX and the alignment error in a Y dimension is ±ΔY.

In one embodiment, each of the conductive pads 404, 410, 416, 422, 428, 434 and 440 have a length and a width which are greater than the lengths and widths of the conductive posts 402, 408, 414, 420, 426, 432 and 432. In another embodiment, the conductive pads 404, 410, 416, 422, 428, 434 and 440 have a length of 2ΔX and a width of 2ΔY. In another embodiment, the conductive posts 402, 408, 414, 420, 426, 432 and 432 have a length and a width of F. Accordingly, the conductive pads 404, 410, 416, 422, 428, 434 and 440 have a length of 2ΔX+F and a width of 2ΔY+F. In another embodiment, the conductive posts 402, 408, 414, 420, 426, 432 and 432 have a width of F_{X} and a length F_{Y}. Accordingly, the conductive pads 404, 410, 416, 422, 428, 434 and 440 may have an adjusted length of 2ΔA +F_{X} and an adjusted width of 2ΔY+F. In yet another embodiment, the size of the conductive pads 404, 410, 416, 422, 428, 434 and 440 is determined by the alignment tolerance of the imprint lithography used to form the conductive traces 400, 406, 412, 418, 424, 430 and 436 and the conductive posts 402, 408, 414, 420, 426, 432 and 432.

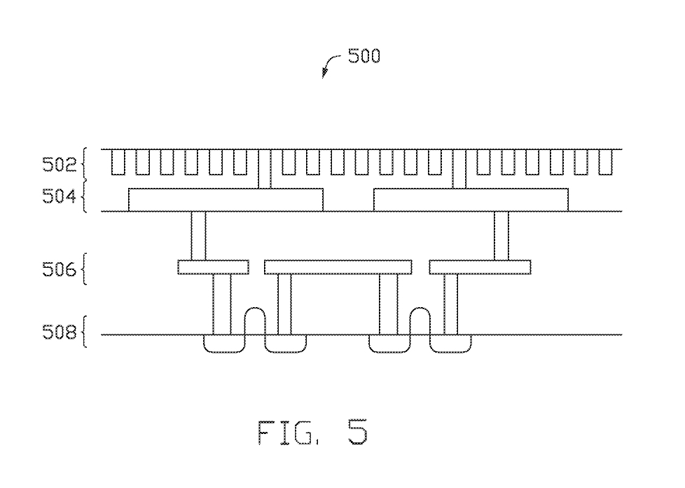

FIG. 5 is a cross-section of a wafer 500 having nano-imprinted patterns 502 representing a cross-point array interconnected to conventionally processed transistor circuitry 508 according to one embodiment described herein. The nano-imprinted patterns 502 are coupled to conductive pads 504, which are in turn connected via conductive posts 506 to conventionally processed transistor circuitry 508.

In one embodiment, the nano-imprinted patterns 502 representing a cross-point array have a very small geometry, the conductive posts 506 have a moderate geometry and the conventionally processed transistor circuitry 508 has a moderate geometry.

In one embodiment, the transistor circuitry 508 may be constructed using one or more transistors where the resulting logic circuits can be bipolar circuits. In another embodiment, the transistor circuitry 508 may be constructed using one or more transistors where the resulting logic circuits can be MOS circuits. If the resulting logic circuits are MOS circuits, the transistor circuitry 508 can consist of NMOS type transistors only, PMOS type transistors only or both NMOS and PMOS transistors (CMOS transistors). The minimum feature size of the nano-imprinted patterns 502 will depend on the geometric capability of the imprint lithography method used in their formation. The minimum feature size of the conventionally processed transistor circuitry 508 will be determined by the geometric capability of the photolithographic process used to form those circuits.

In one embodiment, a photoresist material may be deposited over the conductive pads 504. The nano-imprinted patterns 502 may then be stamped into the photoresist material. In another embodiment, a dielectric material may be deposited over the conductive pads 504. A photoresist material may subsequently be deposited over the dielectric material and the nano-imprinted patterns 502 may then be stamped into the photo resist material.

The present disclosure provides a memory device having nano-imprinted patterns interconnected to conventionally processed circuitry on a wafer and a method of fabrication thereof. The interconnection of nano-imprinted features to photolithographically processed wafer circuitry results in cost effective production of memory devices having very small geometries.

While the foregoing is directed to embodiments of the present disclosure, other and further embodiments of the disclosure may be devised without departing from the basic scope thereof and the scope thereof is determined by the claims that follow.

1. A memory device, comprising:
a plurality of conductive traces, wherein the plurality of conductive traces are disposed in a common plane, wherein a first conductive trace of the plurality of conductive traces has a first length, wherein a second conductive trace of the plurality of conductive traces has a second length and the second length is less than the first length;
a substrate having a plurality of conductive pads formed therein, wherein adjacent conductive pads of the plurality of conductive pads are spaced apart by a distance that is greater than the distance between adjacent traces of the plurality of conductive traces; and
a plurality of conductive posts, wherein a first conductive post of the plurality of conductive posts is coupled between the first conductive trace and a first conductive pad of the plurality of conductive pads, wherein a second conductive post of the plurality of conductive posts is coupled between the second conductive trace and a second conductive pad of the plurality of conductive pads.

2. The memory device of claim 1, wherein each conductive trace of the plurality of conductive traces has a length, a width and a height and each conductive post of the plurality of conductive posts has a length, a width and a height, wherein the width of each conductive post of the plurality of conductive posts is about equal to the width of each trace of the plurality of conductive traces.

3. The memory device of claim 1, wherein each pad of the plurality of conductive pads has a length and a width, wherein the length and the width of each pad of the plurality of conductive pads are greater than a length and a width of each conductive post of the plurality of conductive posts.

4. The memory device of claim 1, further comprising a third conductive trace, wherein the third conductive trace has a third length and the third length is less than the second length.

5. The memory device of claim 4, further comprising a fourth conductive trace having the first length, a fifth conductive trace having the second length and a sixth conductive trace having the third length.

6. The memory device of claim 1, wherein each of the plurality of conductive posts is self-aligned to a conductive trace of the plurality of conductive traces.

7. The method of claim 1, wherein each of the plurality of conductive posts is connected to an end of a conductive trace of the plurality of conductive traces.

8. The method of claim 1, wherein each of the plurality of connective conductive posts is connected to a conductive trace of the plurality of conductive traces at a position along the conductive trace that is spaced from an end.

9. A memory device, comprising:
a plurality of conductive traces disposed in a common plane;
a substrate having a plurality of conductive pads formed therein, wherein a first conductive pad of the plurality of conductive pads is spaced from a second conductive pad of the plurality of conductive pads in both an X dimension and a Y dimension, wherein adjacent conductive pads of the plurality of conductive pads are spaced apart by a distance that is greater than the distance between adjacent traces of the plurality of conductive traces; and
a plurality of conductive posts, wherein a first conductive post of the plurality of conductive posts extends between the first conductive pad and a first conductive trace of the plurality of conductive traces and wherein a second conductive post of the plurality of conductive posts extends between the second conductive pad and a second conductive trace of the plurality of conductive traces.

10. The memory device of claim 9, wherein each trace of the plurality of conductive traces has a length, a width and a height and each conductive post of the plurality of conductive posts has a length, a width and a height, wherein the width of each conductive post of the plurality of conductive posts is about equal to the width of each trace of the plurality of conductive traces.

11. The memory device of claim 9, wherein each conductive pad of the plurality of conductive pads has a length and a width, wherein the length and the width of each pad of the plurality of conductive pads are greater than a length and a width of each conductive post of the plurality of conductive posts.

12. The memory device of claim 9, wherein a third conductive pad of the plurality of conductive pads is spaced from the second conductive pad of the plurality of conductive pads in both an X dimension and Y dimension.

13. The memory device of claim 12, wherein a fourth conductive pad of the plurality of conductive pads is spaced from the third conductive pad of the plurality of conductive pads in both an X dimension and a Y dimension and is co-linear and co-planar with the first conductive pad of the plurality of conductive pads in the Y dimension.

14. The memory device of claim 9, wherein each of the plurality of conductive posts is self-aligned to a conductive trace of the plurality of conductive traces.

15. The memory device of claim 9, wherein each of the plurality of conductive posts is connected to an end of a conductive trace of the plurality of conductive traces.

16. The memory device of claim 9, wherein each of the plurality of connective conductive posts is connected to a conductive trace of the plurality of conductive traces at a position along the conductive trace that is spaced from an end.

17-20. (canceled)
